(19) United States
(12) Patent Application Publication
(10) Pub. No.: US 2025/0306362 A1
(43) Pub. Date: Oct. 2, 2025

(54) LIGHT EMITTING APPARATUS, DISPLAY APPARATUS, IMAGE CAPTURING APPARATUS, AND ELECTRONIC DEVICE

(71) Applicant: CANON KABUSHIKI KAISHA, Tokyo (JP)

(72) Inventors: NORIFUMI KAJIMOTO, Kanagawa (JP); HIROAKI SANO, Tokyo (JP); SHOMA HINATA, Kanagawa (JP); TETSUO TAKAHASHI, Kanagawa (JP); YUHI UEDA, Kanagawa (JP)

(21) Appl. No.: 19/088,297

(22) Filed: Mar. 24, 2025

(30) Foreign Application Priority Data
Mar. 26, 2024 (JP) 2024-049554

(51) Int. Cl. G02B 27/00; G02B 25/00; G02B 27/28; G06F 3/01; H10K 59/65

(52) U.S. Cl. CPC G02B 27/0093; G02B 25/001; G02B 27/283; H10K 59/65; G06F 3/013

(57) ABSTRACT

A light emitting apparatus includes a display region and an infrared light emitting region on a substrate. A plurality of display light emitting elements is disposed in the display region. A plurality of infrared light emitting elements is disposed in the infrared light emitting region. In a plan view of the substrate, the display region and the infrared light emitting region are in a positional relationship not overlapping each other. Each of the display light emitting element and the infrared light emitting element is made by laminating a lower electrode, a functional layer including a light emitting layer, and an upper electrode in this order from the substrate side. A reflectance of the upper electrode of the infrared light emitting element at an infrared wavelength is higher than a reflectance of the upper electrode of the display light emitting element at the infrared wavelength.

### BACKGROUND OF THE INVENTION

### Technical Field

The present disclosure relates to a light emitting apparatus, more specifically, a light emitting apparatus having an infrared emission function for light-of-sight detection, and a display apparatus, an image capturing apparatus, and an electronic device that include the light emitting apparatus.

### Description of the Related Art

An organic light emitting element (an organic electroluminescence element or an organic EL element) is an electronic element including a pair of electrodes (an anode and a cathode) and an organic compound layer disposed therebetween. By injecting electrons and holes from the pair of electrodes, excitons of a luminescent organic compound in the organic compound layer are generated, and the organic light emitting element emits light at the time when the excitons return to a ground state.

The recent progress in organic light emitting elements is remarkable, and low drive voltage, various emission wavelengths, high-speed response, and thickness and weight reduction of light emitting devices are proceeding. For this reason, organic light emitting elements are receiving attention as image display apparatuses, such as a viewfinder of a camera, a head mounted display, and a wearable device called smartglasses.

In such a display apparatus, it is desired to detect a visually recognizing point of a user by detecting the line of sight of the user to the display apparatus and reflect the detected line-of-sight information in driving of the display apparatus.

Japanese Patent Laid-Open No. 2021-015731 (hereinafter, PTL 1) describes an apparatus that detects a line of sight by applying infrared light as detection light to an eye of a user looking into a viewfinder and capturing reflected light from the eye with a detector.

In the display apparatus described in PTL 1, a display unit, an infrared emitting unit for line-of-sight detection, and an infrared image capturing unit are mounted on the same board. When such a display apparatus is viewed with an eyepiece optical system, an eye box needs to be increased in size to reduce a decrease in the contrast of an image and optical performance when the position of an eye of a viewer shifts. For this reason, an angular distribution of light emitted from a display surface of a display region is desirably wider. On the other hand, light of the infrared emitting unit does not need to form a wide eye box.

Furthermore, it is known that lens transmittance deteriorates when the display apparatus is used with a small eyepiece optical system. For this reason, when light of an infrared light emitting element is emitted to the eye via the eyepiece optical system, there is a disadvantage that light intensity remarkably decreases.

### SUMMARY OF THE INVENTION

The present disclosure is contemplated in view of the above problem and provides an advantageous technology to improve the light extraction efficiency of an infrared light emitting element to efficiently deliver infrared light to an eye (particularly, a cornea) in a case of passing through an eyepiece optical system.

An aspect of the present disclosure provides a light emitting apparatus. The light emitting apparatus includes: a display region and an infrared light emitting region on a substrate, a plurality of display light emitting elements being disposed in the display region, a plurality of infrared light emitting elements being disposed in the infrared light emitting region. In a plan view of the substrate, the display region and the infrared light emitting region are in a positional relationship not overlapping each other.

Each of the display light emitting element and the infrared light emitting element is made by laminating a lower electrode, a functional layer including a light emitting layer, and an upper electrode in this order from the substrate side.

A reflectance of the upper electrode of the infrared light emitting element at an infrared wavelength is higher than a reflectance of the upper electrode of the display light emitting element at the infrared wavelength.

Further features of the present disclosure will become apparent from the following description of exemplary embodiments with reference to the attached drawings.

### BRIEF DESCRIPTION OF THE DRAWINGS

FIG. 1 is a schematic plan view that shows an example of a light emitting apparatus according to an embodiment of the present disclosure.

FIG. 2 is a schematic sectional view of the light emitting apparatus, taken along the line II-II in FIG. 1.

FIG. 3 is a schematic sectional view that shows an example of a light emitting apparatus according to another embodiment of the present disclosure and is a sectional view taken along the line corresponding to the line II-II in FIG. 2.

FIG. 4 is a diagram that illustrates detection of a line of sight of a viewer with the light emitting apparatus according to the embodiment of the present disclosure.

FIG. 5 is a diagram that illustrates an example of the light emitting apparatus according to another embodiment (a mode used together with an eyepiece optical system) of the present disclosure.

FIG. 6 is a schematic exploded view that shows an example of a display apparatus according to an embodiment of the present disclosure.

FIG. 7A is a schematic view that shows an example of an image capturing apparatus according to an embodiment of the present disclosure. FIG. 7B is a schematic view that shows an example of an electronic device according to an embodiment of the present disclosure.

FIG. 8A is a schematic view that shows an example of a display apparatus according to an embodiment of the present disclosure. FIG. 8B is a schematic view that shows an example of a foldable display apparatus.

FIG. 9A is a schematic view that shows an example of a wearable device according to an embodiment of the present disclosure. FIG. 9B is a schematic view that shows another example of a wearable device according to an embodiment of the present disclosure.

### DESCRIPTION OF THE EMBODIMENTS

Hereinafter, embodiments of the present disclosure will be described with reference to the attached drawings. The invention is not limited to only the embodiments described and may be variously modified within the scope of the present disclosure. Like reference signs denote portions having the same functions in the drawings described below, and the description thereof may be omitted or simplified.

In the embodiments of the present disclosure, the phrase “greater than or equal to XX and less than or equal to YY” or the phrase “XX to YY” that indicates a numeric range means a numeric range including a lower limit and an upper limit that are end points unless otherwise noted. In a case where a numeric ranges is described in a stepwise manner, a selected combination of an upper limit and a lower limit of each numeric range may be determined.

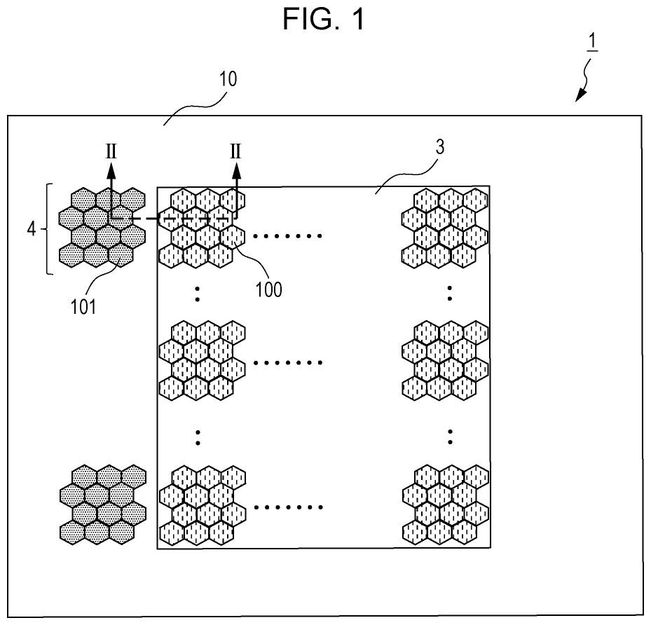

Light emitting apparatuses according to embodiments of the present disclosure will be described with reference to FIGS. 1 to 5. FIG. 1 is a schematic plan view that shows an example of the light emitting apparatus according to an embodiment of the present disclosure. Here, a plan view is a view when viewed in a direction perpendicular to the principal surface of a substrate or insulating layer (a normal direction of the principal surface). A side on which a functional layer including a light emitting layer is provided with respect to the substrate or the insulating layer is referred to as an upper side, and its opposite side is referred to as a lower side. In the embodiment of the present disclosure, a side on which light exits is the upper side.

As shown in FIG. 1, the light emitting apparatus 1 includes a display region 3 and a non-display region 10.

In FIG. 1, an infrared light emitting region 4 that can exercise an infrared emission function for line-of-sight detection is disposed in the non-display region 10. The display region 3 and the infrared light emitting region 4 are disposed on an insulating layer 2 provided on the substrate. The display region 3 and the infrared light emitting region 4 may be disposed on the substrate via an insulating layer or may be directly disposed on the substrate. When the display region 3 and the infrared light emitting region 4 are directly disposed on the substrate, the substrate may be made of an insulating material to form an insulating layer. Not only the infrared light emitting region 4 but also an image capturing unit (including a plurality of image pickup elements and light receiving elements) for detecting reflected light (infrared reflected light) from an eye when infrared light emitted from the infrared light emitting region 4 (more specifically, a plurality of infrared light emitting elements 101) reaches the eye, a drive circuit and the like (not shown) including active elements, such as transistors, for performing appropriate display in the display region 3 can be disposed in the non-display region 10.

In FIG. 1, the non-display region 10 is provided so as to surround the display region 3; however, the non-display region 10 is not limited thereto. For example, the non-display region 10 may be provided along only one side of the display region 3 or may be provided only two or three sides of the display region 3.

The display region 3 is a region in which a plurality of display light emitting elements 100 is arranged. The display light emitting element 100 emits light, more specifically, visible light (display light) and is called a pixel or a sub-pixel. In FIG. 1, the display light emitting elements 100 are arranged in a two-dimensional array on the insulating layer 2 provided on the substrate (not shown). In FIG. 1, an array of the display light emitting elements in a plane is a delta array. The array of the display light emitting elements in a plane may be a stripe array, a square array, a pentile array, or a Bayer array. By arranging primary pixels in a matrix, a light emitting apparatus having a high pixel count or display apparatus can be provided. The color of light emitted from the display light emitting element 100 that is a component of the display region 3 is not limited, and the display light emitting element 100 may be configured to emit yellow light, white light, or the like, other than red light, green light, or blue light. The plurality of display light emitting elements can respectively emit different colors to form an image or the like.

The infrared light emitting region 4 is a region in which a plurality of infrared light emitting elements 101 is arranged on the insulating layer 2 provided on the substrate (not shown). The arrangement position of the infrared light emitting region 4 is not limited. For example, the infrared light emitting region 4 may be disposed so as to be located outside the display region 3 in a plan view of the substrate. The infrared light emitting elements 101 emit infrared light. An array of the infrared light emitting elements 101 in a plane may be any one of a stripe array, a square array, a delta array, a pentile array, and a Bayer array. The configuration of the infrared light emitting region 4 is not limited as long as the infrared light emitting region 4 includes infrared light emitting elements capable of emitting infrared light. The infrared light emitting region 4 may include, for example, organic light emitting elements, LED elements, or the like, other than infrared light emitting elements.

In the following description, the term “light emitting element” can be used as a term including the “display light emitting element” and the “infrared light emitting element”.

In the embodiment of the present disclosure, the display region 3 and the infrared light emitting region 4 are disposed on the substrate so as not to overlap each other in a plan view of the substrate. FIG. 1 shows a planar positional relationship between the display region 3 and the infrared light emitting region 4. In FIG. 1, the display region 3 and the infrared light emitting region 4 are disposed so as to be defined on the same substrate. A method of disposing the display region 3 and the infrared light emitting region 4 such that the display region 3 and the infrared light emitting region 4 do not overlap each other is not limited. The display region 3 and the infrared light emitting region 4 may be disposed so as to be defined on the same substrate or may be respectively disposed on different substrates.

### [Display Light Emitting Element]

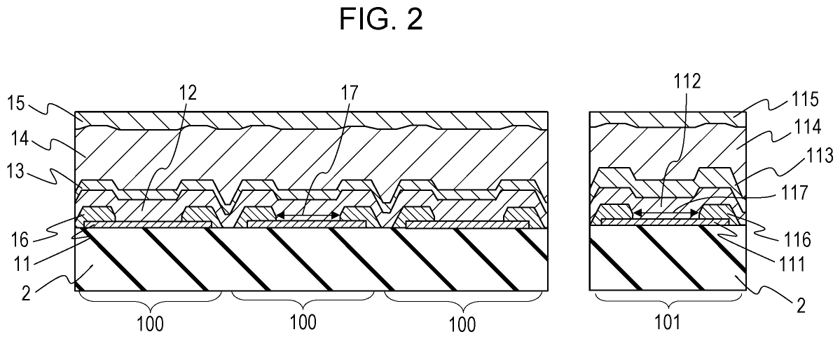

The display light emitting element 100 may be formed by laminating a first electrode, a functional layer including a light emitting layer (or a light emitting substance), and a second electrode on the substrate in this order from the substrate side. The first electrode and the second electrode are also referred to as a lower electrode and an upper electrode based on their arrangement positions. FIG. 2 is a schematic sectional view of the light emitting apparatus, taken along the line II-II in FIG. 1. In FIG. 2, the display light emitting element 100 is formed by laminating a lower electrode (first lower electrode) 11, a functional layer 12 including a light emitting layer, an upper electrode (first upper electrode) 13, a protective layer 14, and a planarization layer 15 on the insulating layer 2 provided on substrate (not shown) in this order. In FIG. 2, reference sign 16 indicates a pixel define layer (PDL) provided so as to cover a peripheral edge portion (end portions in FIG. 2) of the lower electrode 11.

The pixel define layer 16 has an aperture portion formed such that part of the lower electrode 11 is exposed and is also called a partition wall, a bank, or the like. A part of the lower electrode 11, not in contact with the pixel define layer 16, may be in contact with the functional layer 12 including a light emitting layer. A region in which the lower electrode 11 and the functional layer 12 are in contact with each other is a light emitting region 17 that produces light when an electric field is applied between the lower electrode 11 and the upper electrode 13. In the present embodiment, the lower electrode 11 and the functional layer 12 are in contact with each other at the aperture portion, and the aperture portion makes up the light emitting region 17. In other words, the pixel define layer 16 may have a function to define the light emitting region of the display light emitting element 100 and can make it possible to accurately form the light emitting region 17 to a desired shape. The pixel define layer 16 may have a function to electrically insulate the lower electrodes of adjacent two light emitting elements from each other. When no pixel define layer 16 is provided, the light emitting region 17 can be defined by the shape of the lower electrode 11. A plan view shape of the aperture portion of the pixel define layer 16, that is, the light emitting region 17, is not limited. For example, the plan view shape of the aperture portion of the pixel define layer 16 may be a circular or elliptical shape, or may be a polygonal shape, such as a hexagonal shape and a quadrangular shape, or may be another shape. Alternatively, a plurality of light emitting regions may be provided for one light emitting element by disposing a plurality of aperture portions of the pixel define layer 16 such that the aperture portions are assigned to one light emitting element.

A protective layer, a color filter, a lens (such as a microlens), or the like may be provided on an electrode that is a cathode. In the present embodiment, the upper electrode 13 is a cathode, and the lower electrode 11 is an anode; however, the lower electrode may be a cathode, and, in this case, the upper electrode may be an anode.

A planarization layer may be provided on the protective layer. When a color filter is provided, a planarization layer may be provided between the color filter and the protective layer. The planarization layer may be made of acrylic resin or the like. This also applies to a case where the planarization layer is provided between the color filter and the microlens.

### [Infrared Light Emitting Element]

The infrared light emitting element 101 may be formed by laminating a third electrode, a functional layer including a light emitting layer (or a light emitting substance), and a fourth electrode on the substrate in this order from the substrate side. The third electrode and the fourth electrode are also referred to as a lower electrode and an upper electrode based on their arrangement positions. In FIG. 2, the infrared light emitting element 101 is formed by laminating a lower electrode (second lower electrode) 111, a functional layer 112 including a light emitting layer, an upper electrode (second upper electrode) 113, a protective layer 114, and a planarization layer 115 on the insulating layer 2 provided on the substrate (not shown) in this order. In FIG. 2, reference sign 116 indicates a pixel define layer provided so as to cover a peripheral edge portion of the lower electrode 111. The pixel define layer 116 is as described for the pixel define layer 16.

A protective layer, a color filter, a lens (such as a microlens), or the like may be provided on an electrode that is a cathode. In the present embodiment, the upper electrode 113 is a cathode, and the lower electrode 111 is an anode; however, the lower electrode may be a cathode, and, in this case, the upper electrode may be an anode.

A planarization layer may be provided on the protective layer. When a color filter is provided, a planarization layer may be provided between the color filter and the protective layer.

The infrared light emitting element 101 can be made up of an organic light emitting element. With the above configuration, the display light emitting element and the infrared light emitting element can be manufactured in the same process.

In the embodiment of the present disclosure, in the infrared light emitting element 101, a reflectance of the upper electrode (second upper electrode) 113 at the infrared wavelength (a reflectance in an infrared wavelength range) is higher than a reflectance of the upper electrode (first upper electrode) 13 of the display light emitting element 100 at the infrared wavelength. Here, the term “reflectance” means the reflectance of the upper electrode of the light emitting layer at the infrared wavelength. When the reflectance is increased, the proportion of light emitted from the substrate in the normal direction with respect to the principal surface of the substrate increases because of the effect of interference, so it is possible to efficiently guide light to the eye of the viewer. For example, the reflectance of the second upper electrode 113 can be set so as to be higher than or equal to 15%. In view of the purpose of the present disclosure (improvement in light extraction efficiency, and the like), the reflectance of the second upper electrode 113 is set so as to be preferably higher than or equal to 15% and lower than or equal to 90%, more preferably higher than or equal to 35% and lower than or equal to 80%, and further preferably higher than or equal to 54% and lower than or equal to 77%. A difference in reflectance between the second upper electrode 113 and the first upper electrode 13 may be set to, for example, 1% or higher, preferably set to 10% or higher, and more preferably set to 50% or higher.

The thickness of the upper electrode (the thickness (film thickness) of a layer forming the upper electrode) is not limited as long as the reflectance of the second upper electrode is higher than the reflectance of the first upper electrode. Therefore, the thickness of the first upper electrode may be thicker or may be thinner than the thickness of the second upper electrode.

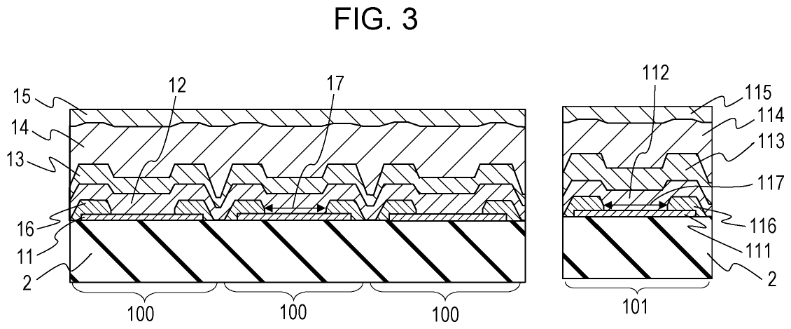

FIG. 3 is a schematic sectional view that shows an example of a light emitting apparatus according to another embodiment of the present disclosure. In FIG. 3, the second upper electrode 113 is formed such that the thickness of the second upper electrode 113 is thicker than the thickness of the first upper electrode 13. When the first upper electrode and the second upper electrode have the same composition and, particularly, are made up of metal films having the same composition, the thickness of the second upper electrode can be thicker than the thickness of the first upper electrode.

### [Formation of Electrode or Layer Between Light Emitting Elements]

When there is a common electrode or layer between one light emitting element and the other light emitting element, the electrode or layer may be disposed astride the one light emitting element and the other light emitting element as long as no adverse effect is given to the light extraction structure.

For example, the first upper electrode 13 may be disposed over the second upper electrode 113. In this case, the second upper electrode 113 may be formed by common film formation together with the first upper electrode 13. For example, as part of the upper electrode (second upper electrode) of the infrared light emitting element, the upper electrode 13 of the display light emitting element may be formed so as to extend to a predetermined position of the infrared light emitting element, and then the second upper electrode 113 may be formed by additional film formation. On the other hand, the second upper electrode 113 may be formed through separate film formation from the first upper electrode 13.

### Substrate

The substrate that is a component of the light emitting element is made up of a sheet-like member having a principal surface. The substrate may be a semiconductor substrate, such as a silicon substrate, or may be an insulating substrate made of glass, quartz, resin, or the like. The substrate may have flexibility. The material of the substrate includes at least one of quartz, glass, silicon, resin, and metal. The substrate may include a switching element, such as a transistor, and a wire. The substrate itself may have an insulation property or an insulating layer (insulating film) may be provided on the substrate. The insulating layer may be made of any material as long as a contact hole can be formed such that a wire can be formed between the insulating layer and the lower electrode (a first electrode or a third electrode) and insulation from a non-connected wire can be ensured. The insulating layer may be, for example, a resin, such as polyimide, silicon oxide, silicon nitride, or the like.

### Insulating Layer

In the present embodiment, the insulating layer 2 is provided on the substrate. The insulating layer may be made of an inorganic material, such as silicon nitride (SiN), silicon oxynitride (SiON), and silicon oxide (SiO). A known technique, such as a sputtering method and a chemical vapor deposition method (CVD method), may be used to form the insulating layer. Alternatively, the insulating layer may be made of an organic material, such as acrylic resin and polyimide resin.

### Electrodes

A pair of electrodes may be used as the electrodes of the light emitting element. The pair of electrodes may be an anode and a cathode. When an electric field is applied in a direction in which the light emitting element emits light, the electrode having a higher potential is an anode, and the other electrode is a cathode. In other words, the electrode that supplies holes to a light emitting layer or a light emitting substance is an anode, and the electrode that supplies electrons is a cathode. In the light emitting element according to the embodiment of the present disclosure, the lower electrode (a first electrode and a third electrode) is an anode, and the upper electrode (a second electrode and a fourth electrode) is a cathode (light extraction electrode); however, the lower electrode may be a cathode, and, in this case, the upper electrode is an anode.

### Anode

A component material of the anode can be the one with a work function that is as large as possible. For example, a metal chemical element, such as gold, platinum, silver, copper, nickel, palladium, cobalt, selenium, vanadium, and tungsten, or a mixture containing one or some of these metal chemical elements may be used for the anode. Alternatively, an alloy made of a combination of some of these metal chemical elements, or a metal oxide, such as a tin oxide, a zinc oxide, an indium oxide, an indium tin oxide (ITO), and an indium zinc oxide, may be used for the anode. A conductive polymer, such as polyaniline, polypyrrole, and polythiophene, may be used for the anode.

Any one of these electrode materials may be used solely or two or more types of these materials may be used together. The anode may be made up of one layer or may be made up of a plurality of layers.

When the electrode of the light emitting element is used as a reflecting electrode, for example, chromium, aluminum, silver, titanium, tungsten, molybdenum, an alloy of some of these materials, a laminate of some of these materials, or the like may be used as the electrode material. The above materials may be used to function as a reflective film that does not serve as an electrode. When used as a transparent electrode, a transparent conductive oxide layer of an indium tin oxide (ITO), an indium zinc oxide, or the like may be used; however, the material is not limited thereto. Photolithography may be used to form electrodes.

### Cathode

On the other hand, the component material of the cathode can be the one with a small work function. Examples of the component material of the cathode include alkali metals, such as lithium, alkaline earth metals, such as calcium, metal chemical elements, such as aluminum, titanium, manganese, silver, lead, and chromium, and mixtures containing one or some of these metal chemical elements. Alternatively, an alloy made of a combination of some of these metal chemical elements may be used. For example, magnesium-silver, aluminum-lithium, aluminum-magnesium, silver-copper, zinc-silver, or the like may be used. A metal oxide, such as an indium tin oxide (ITO), may also be used. One type of these electrode materials may be used solely or two or more types of these electrode materials may be used together. The cathode may be made up of a single layer or may be made up of multiple layers. Among others, silver can be used, and a silver alloy can be further used to reduce aggregation of silver. As long as aggregation of silver is reduced, the ratio of an alloy does not matter. For example, the ratio of silver to another metal may be one to one, three to one, or the like.

A cathode may be made as a top emission element by using an oxide conductive layer made of ITO or the like or may be made as a bottom emission element by using a reflecting electrode made of aluminum (Al) or the like. The arrangement of the cathode is not limited. A method of forming the cathode is not limited. When a direct-current sputtering method, an alternating-current sputtering method, or the like is used, the film has a good coverage, and it is easy to reduce the resistance, so it is more desirable.

In the present embodiment, each of the upper electrodes 13, 113, which are cathodes, is disposed on the functional layer 12 or the functional layer 112 and have translucency. Specifically, the upper electrodes 13, 113 each make up a semi-transparent electrode made of a translucent material having properties (that is, translucent reflection properties) to transmit part of light reaching the surface and reflect the other part. The material of the upper electrodes 13, 113 can be selected from among transparent conductive oxides, such as ITO, IZO, AZO, and IGZO, and translucent materials made of metal materials. Examples of the metal materials include element metals, such as aluminum, silver, and gold, alkali metals, such as lithium and cesium, alkaline earth metals, such as magnesium, calcium, and barium, and alloy materials containing at least any one of these metal materials. An alloy mainly containing magnesium or silver can be selected as a translucent material. As long as the upper electrodes 13, 113 have desired transmittances, the upper electrodes 13, 113 may be laminates of layers of the above-described materials. In FIG. 3, the first upper electrode 13 is an oxide transparent electrode made of a transparent conductive oxide, and the second upper electrode 113 is made of a metal material. Each of the upper electrodes 13, 113 may be disposed separately for each light emitting element or may be disposed astride the plurality of light emitting elements.

Therefore, one upper electrode 13 or one upper electrode 113 may be disposed in the light emitting apparatus 1.

### Functional Layer

The functional layer includes a light emitting layer or a light emitting substance and is disposed on the lower electrode. The functional layer can be formed by using a known technique, such as a vapor deposition method and a spin coating method. The functional layer may be made up of a single layer or may be made up of a plurality of layers. A plurality of layers may include a hole injection layer, a hole transport layer, an electron blocking layer, a light emitting layer, a hole blocking layer, an electron transport layer, an electron injection layer, and the like. Another layer, such as a charge generation layer and an electron block layer, may be included between these layers.

Holes injected from an anode and electrons injected from a cathode recombine in the light emitting layer to emit light. The light emitting layer or the light emitting substance may be inorganic or may be organic. When the light emitting layer or the light emitting substance is organic, the light emitting apparatus may be referred to as an “organic light emitting apparatus”, and the light emitting element may be referred to as an “organic light emitting element”. When the functional layer is an organic compound layer, the organic compound layer just needs to be mainly made of an organic compound and may include inorganic atoms or an inorganic compound. The organic compound layer may include, for example, copper, lithium, magnesium, aluminum, iridium, platinum, molybdenum, zinc, or the like. When the light emitting layer or the light emitting substance in the functional layer of the display light emitting element is organic, that is, when the display light emitting element is made up of an organic light emitting element, the infrared light emitting element can also be an organic light emitting element. In this case, the display light emitting element and the infrared light emitting element can be manufactured in the same process.

The functional layer may be disposed between the lower electrode and the upper electrode and may be disposed in contact with the lower electrode and the upper electrode. The functional layer may be disposed separately for each light emitting element or may be disposed astride the plurality of light emitting elements. Therefore, one functional layer may be disposed in the light emitting apparatus 1.

A light emitting material used to form the light emitting layer may be a material, such as a fluorescent material, a phosphorescent material, and a delayed fluorescent material, or may be a quantum dot, such as CdS and perovskite. The light emitting substance may be a substance that is a component of these materials and quantum dots. The light emitting layer may be made up of multiple layers or may be made up of a single layer. When there is a light emitting layer made up of multiple layers, a red light emitting material, a green light emitting material, and a blue light emitting material can be contained in layers of the light emitting layer. White light can be obtained by mixing light emitting colors. Light emitting materials of complementary colors, such as a blue light emitting material and a yellow light emitting material, may be contained in functional layers.

### Organic Compound Layer

When the functional layer including the light emitting layer is an organic compound layer, the organic compound layer (such as a hole injection layer, a hole transport layer, an electron blocking layer, a light emitting layer, a hole blocking layer, an electron transport layer, and an electron injection layer) can be formed by using a dry process, such as a vacuum evaporation method, an ionized evaporation method, a sputtering method, and a plasma method. Instead of the dry process, a wet process in which a layer is formed with a known coating method (such as spin coating, dipping, a casting method, an LB method, and an ink-jet method) by dissolving an organic compound in an appropriate solvent may be used. When a layer is formed with a vacuum evaporation method, a solution coating method, or the like, crystallization or the like is less likely to occur, and it is excellent in temporal stability. When a film is formed with a coating method, the film may be formed in combination with an appropriate binder resin.

The binder resin may be polyvinyl carbazole resin, polycarbonate resin, polyester resin, ABS resin, acrylic resin, polyimide resin, phenolic resin, epoxy resin, silicon resin, urea resin, or the like; however, the binder resin is not limited to these materials. One type of these binder resins may be used solely as a homopolymer or a copolymer or two or more types of these binder resins may be mixed and used. Furthermore, as needed, an additive, such as a known plasticizer, a known oxidation inhibitor, and a known ultraviolet absorbent, may be used together.

### [Pixel Define Layer]

A pixel define layer (PDL) is made up of a silicon nitride (SiN) film, a silicon oxynitride (SiON) film, or a silicon oxide (SiO) film formed with a chemical vapor deposition method (CVD method). To increase the resistance of the functional layer, particularly, the resistance in an in-plane direction of an organic compound layer, the organic compound layer, particularly, the hole transport layer can be formed thin at a side wall of the pixel define layer. Specifically, an eclipse during vapor deposition is increased by reducing a taper angle of a side wall of the pixel define layer or increasing the film thickness of the pixel define layer, with the result that the film thickness of the side wall can be made thin.

On the other hand, the side wall taper angle of the pixel define layer or the film thickness of the pixel define layer can be adjusted to such an extent that no air gap is formed in the protective layer formed on the pixel define layer. Since no air gap is formed in the protective layer, it is possible to reduce occurrence of defects in the protective layer. Since occurrence of defects in the protective layer is reduced, it is possible to reduce a decrease in reliability, such as occurrence of a dark spot and occurrence of poor conduction of the second electrode.

According to the present embodiment, even when the taper angle of the side wall of the pixel define layer is not steep, it is possible to effectively suppress leakage of electric charge to an adjacent pixel. As a result of study made by the inventor, it is found that leakage of electric charge can be sufficiently reduced when the taper angle falls within the range larger than or equal to 60 degrees and smaller than or equal to 90 degrees. The film thickness of the pixel define layer is desirably greater than or equal to 10 nm and less than or equal to 150 nm. A similar effect is obtained even with a configuration including only a pixel electrode and not including a pixel define layer. However, in this case, a short circuit of the light emitting element, particularly, the organic light emitting element, can be reduced by setting the film thickness of the pixel electrode to a half of the functional layer or less or forming a pixel electrode end in a forward tapered shape with an angle smaller than 60 degrees.

### Protective Layer

A protective layer may be provided on the upper electrode in the light emitting element. For example, when glass provided with a humectant is bonded onto the upper electrode, entry of water or the like to the functional layer, particularly, the organic compound layer, is reduced, so it is possible to reduce occurrence of poor display. In another embodiment, a passivation film made of silicon nitride or the like may be provided on a cathode to reduce entry of water or the like to the functional layer. For example, the protective layer may be provided by conveying the cathode after being formed to another chamber without breaking a vacuum and forming a 2-μm-thick silicon nitride film by CVD. After deposition with CVD, a protective layer using atomic layer deposition (ALD) may be provided. The material of the film formed by ALD is not limited and may be a silicon nitride, a silicon oxide, an aluminum oxide, or the like. A silicon nitride may be formed by CVD further on the film formed by ALD. The film thickness of the film formed by ALD may be less than the film thickness of the film formed by CVD. Specifically, the film thickness of the film formed by ALD may be less than or equal to 50% of the film thickness of the film formed by CVD and, furthermore, may be less than or equal to 10% of the film thickness of the film formed by CVD. The protective layer may be disposed over a plurality of display light emitting elements and a plurality of infrared light emitting elements.

### Color Filter

A color filter may be provided on the protective layer in the light emitting element. For example, color filters designed in consideration of the size of each light emitting element may be provided on another substrate, and the substrate may be bonded to a substrate on which the light emitting elements are provided. Alternatively, color filters may be patterned on the above-described protective layer by using photolithography. A color filter may be made of a high polymer.

### Planarization Layer

When a color filter is provided on the protective layer in the light emitting element, a planarization layer (planarizing film) may be provided between the color filter and the protective layer. The planarization layer is provided for the purpose of reducing the irregularities of the lower layer. When the purpose is not limited, the planarization layer may be referred to as a resin layer. The planarization layer may be made of an organic compound and may be a low-molecular compound or a macromolecular compound. The planarization layer can be a macromolecular compound.

The planarization layer may be provided on the upper and lower sides of the color filter, and the component materials of those layers may be the same or may be different. Specifically, the planarization layer may be polyvinyl carbazole resin, polycarbonate resin, polyester resin, ABS resin, acrylic resin, polyimide resin, phenolic resin, epoxy resin, silicon resin, urea resin, or the like.

### Optical Member

The light emitting element may include an optical member on its light emission side, for example, on the planarization layer. The optical member may be a lens or the like and may be specifically a microlens. The microlens is not limited to a spherical microlens and may be an aspherical microlens, an asymmetrical microlens, or a digital microlens. The microlens may be a lens with a small diameter. The microlens can be made of acrylic resin, epoxy resin, or the like. The microlens may be provided for the purpose of increasing the amount of light extracted from the light emitting element and controlling the direction in which light is extracted. The microlens may have a hemispherical shape. When the microlens has a hemispherical shape, there is a tangent parallel to the principal surface of the substrate among tangents that are tangent to the hemisphere, and a point of contact between the parallel tangent and the hemisphere is the vertex of the microlens. The vertex of the microlens can be similarly determined even in a selected sectional view. In other words, there is a tangent parallel to the principal surface of the substrate among tangents that are tangent to a semicircle of the microlens in the sectional view, and a point of contact between the parallel tangent and the semicircle is the vertex of the microlens.

The middle point of the microlens can be defined. In the cross section of the microlens, a line segment from a point at which a circular arc shape ends to another point at which the circular arc shape ends is assumed, and the middle point of the line segment can be called as the middle point of the microlens. A cross section to determine a vertex or a middle point may be a cross section perpendicular to the substrate.

The microlens has a first surface having a convex portion and a second surface opposite to the first surface. The second surface can be disposed on the functional layer side with respect to the first surface. To provide such a configuration, the microlens needs to be formed on the light emitting element. When the functional layer is an organic compound layer, a process accompanied by high temperature can be avoided in a manufacturing process. Furthermore, when the functional layer is an organic compound layer and the second surface is disposed on the organic compound layer side with respect to the first surface, all the glass transition temperatures of organic compounds that make up the organic compound layer are preferably higher than or equal to 100° C. and more preferably higher than or equal to 130° C.

### Counter Substrate

A counter substrate may be disposed on the planarization layer. Because the counter substrate is provided at a position so as to face the above-described substrate, it is called a counter substrate. The component material of the counter substrate may be the same as that of the substrate. When the substrate is a first substrate, the counter substrate may be a second substrate.

### Pixel Circuit

The light emitting apparatus may include pixel circuits connected to the light emitting elements. The pixel circuits may be of an active matrix type that independently controls a light emitting element (first display light emitting element) and another light emitting element (second display light emitting element). The active-matrix circuit may operate in accordance with voltage programming or current programming.

The drive circuit has a pixel circuit for each pixel. The pixel circuit may include first and second display light emitting elements, transistors that control the emission luminances of the first and second display light emitting elements, transistors that control light emission timings, capacitors that hold the gate voltages of the transistors that control the emission luminances, and transistors for connection with a GND without intervening the first or second display light emitting element.

The light emitting apparatus may be configured to include a display region and a surrounding region (non-display region) disposed around the display region. The display region may include pixel circuits, and the surrounding region may include a display control circuit. The mobility of a transistor that is a component of the pixel circuit may be smaller than the mobility of a transistor that is a component of the display control circuit. The slope of the current-voltage characteristics of a transistor that is a component of the pixel circuit may be smaller than the slope of the current-voltage characteristics of a transistor that is a component of the display control circuit. The slope of the current-voltage characteristics can be measured in accordance with so-called Vg-Ig characteristics. A transistor that is a component of the pixel circuit may be a transistor connected to the light emitting element, such as a first light emitting element.

### Pixel

The light emitting apparatus includes a plurality of pixels. Each pixel has sub-pixels that emit light in different colors from each other, that is, display light emitting elements. The sub-pixels may respectively have, for example, RGB light emitting colors.

The pixel emits light in a region also called a pixel aperture. This region is the same as a first region. The pixel aperture may be less than or equal to 15 μm and may be greater than or equal to 5 μm. More specifically, the pixel aperture may be 11 μm, 9.5 μm, 7.4 μm, 6.4 μm, or the like. An interval between the sub-pixels may be less than or equal to 10 μm and, specifically, may be 8 μm, 7.4 μm, or 6.4 μm.

The pixels can take a known arrangement mode in a plan view. The pixels may be arranged in, for example, a stripe array, a delta array, a pentile array, or a Bayer array. The shape of each sub-pixel in a plan view may be any one of known shapes. The shape of each sub-pixel in a plan view is, for example, a quadrangular shape, such as a rectangular shape and a rhombic shape, a hexagonal shape, or the like. When the shape of each sub-pixel is a shape close to, for example a rectangular shape, the shape is assumed to be included in a rectangular shape. Therefore, the shape of each sub-pixel just needs to be a shape approximated to the any one of known shapes. The pixels may be configured by combining the shape of each sub-pixel with a pixel array.

### [Line-of-Sight Detection Operation of Light Emitting Apparatus According to Embodiment of Present Disclosure]

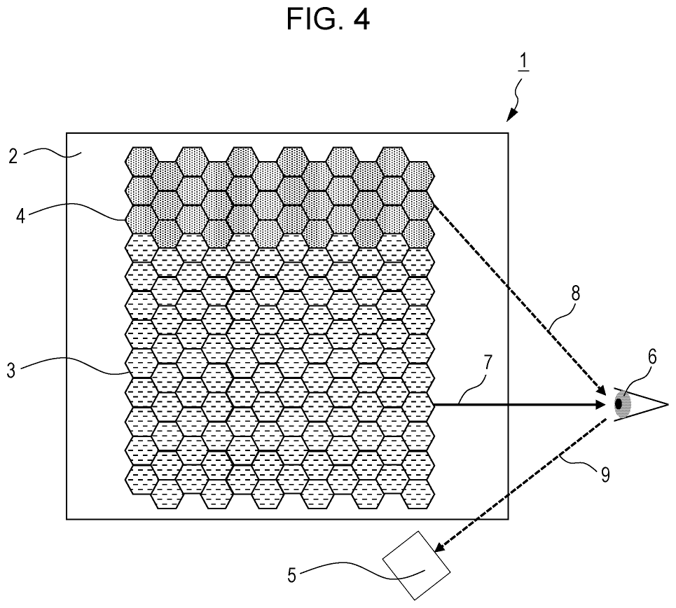

The line-of-sight detection operation of the light emitting apparatus according to the embodiment of the present disclosure will be described with reference to FIG. 4.

FIG. 4 is a schematic diagram that shows an example of the configuration of the light emitting apparatus 1 according to the embodiment of the present disclosure. The light emitting apparatus 1 includes a display unit made up of the display region 3 and an infrared emitting unit made up of the infrared light emitting region 4. In FIG. 4, when a principal surface of the insulating layer 2 (the substrate when no insulating layer 2 is provided), having a light emitting region, in the light emitting apparatus 1 is oriented toward a user (viewer), and the user can use the light emitting apparatus 1. An external system (not shown) can be present outside the light emitting apparatus 1, and the light emitting apparatus 1 is connected to this external system.

The display unit includes a plurality of display light emitting elements. The display unit is capable of emitting display light 7 to form a display image or being used as a light source used for illumination. A display image may be an image (or picture), such as a still image and a moving image, and may be a monochrome image or a full-color image.

On the other hand, the infrared emitting unit includes a plurality of infrared light emitting elements and emits infrared light 8 to the eye 6 of the viewer gazing at a display image.

The image capturing unit 5 includes a plurality of image pickup elements and a plurality of light receiving elements and is disposed in the non-display region 10. The image capturing unit 5 just needs to include image pickup elements having sensitivity in the infrared range. For example, a photodiode, an organic photoelectric conversion element, an inorganic photoelectric conversion element, or the like may be selected as the image pickup element. The image capturing unit 5 may be formed on the same substrate or insulating layer 2 as the display region 3 and the infrared light emitting region 4 or may be formed on another substrate or insulating layer as a separate member. It is possible to reduce erroneous detection due to incident visible light, so an infrared filter that transmits only infrared light may be provided on the image pickup element.

The image capturing unit 5 detects reflected light (infrared reflected light) 9 from the eye 6 when the infrared light 8 emitted from the infrared light emitting region 4 (more specifically, infrared light emitting elements) reaches the eye 6. Thus, a captured image of the eye 6 is obtained. In other words, the line of sight of the user (viewer) to the display image is detected from the captured image of the eye 6, obtained through imaging with the infrared light 8. A selected known technique may be applied to line-of-sight detection using the captured image of the eye 6. In an example, a line-of-sight detection method based on a Purkinje image caused by reflection of irradiation light on a cornea may be used.

More specifically, a line-of-sight detection process based on a pupil-cornea reflection method is performed. A line-of-sight vector indicating the orientation (rotational angle) of the eye 6 is calculated in accordance with the pupil image contained in a captured image of the eye 6 and a Purkinje image by using the pupil-cornea reflection method. Thus, the line of sight of a user is detected.

[Configuration in which Light Emitting Apparatus is Used Together with Eyepiece Optical System]

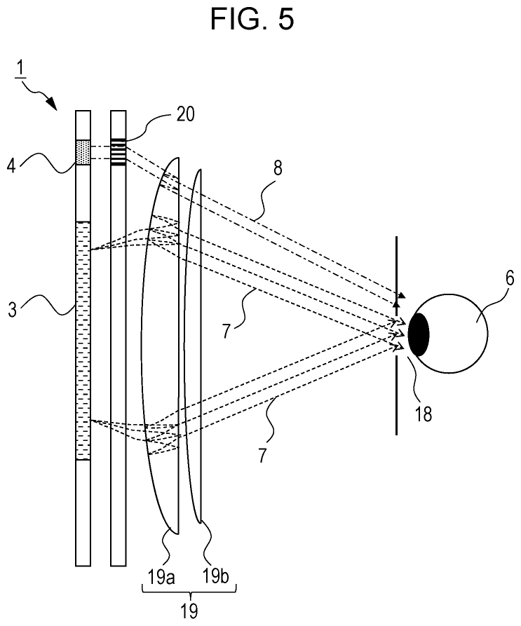

In the embodiment of the present disclosure, the light emitting apparatus may be used together with an eyepiece optical system. FIG. 5 shows an example in which the light emitting apparatus 1 is used together with the eyepiece optical system 19 as an example of the embodiment. The dashed line arrows represent light (pencil of light rays) 7 that exits from the display region 3 of the light emitting apparatus 1 and enters the eye 6 via the eyepiece optical system 19. The alternate long and short dashed line arrows represent light (pencil of light rays) 8 that exits from the infrared light emitting region 4 of the light emitting apparatus 1 and enters the eye 6 via the eyepiece optical system 19.

The light 7 that is emitted from the display region 3 of the light emitting apparatus 1 forms an exit pupil 18 via the eyepiece optical system 19. The exit pupil 18 is desirably greater as much as possible. In other words, the width of the pencil of light rays 7 emitted from the display light emitting elements 100 of the display region 3 is desirably greater as much as possible. For example, the size of the exit pupil 18 can be greater than or equal to 10 mm. As the reflectance of the first upper electrode 13 (the reflectance in the infrared wavelength range) is increased, the width of the pencil of light rays 7 reduces. Therefore, the reflectance of the first upper electrode 13 is desirably not too high. For example, the reflectance of the first upper electrode 13 may be lower than or equal to 85%. The reflectance of the first upper electrode 13 is preferably higher than or equal to 1% and lower than or equal to 85%, more preferably higher than or equal to 1% and lower than or equal to 79%, and further preferably higher than or equal to 1% and lower than or equal to 76%.

On the other hand, the width of the pencil of light rays 8 emitted from the infrared light emitting region 4 may be small. For example, the width of the pencil of light rays 8 may be less than or equal to 10 mm. When the width of the pencil of light rays 8 is reduced, implementation of a mode in which light is more condensed is possible, so light efficiently reaches the eye 6 of the viewer. In this case, the reflectance of the second upper electrode 113 can be increased.

To project the pencil of light rays 8 from the infrared light emitting region 4 from the front of the eye 6 of the viewer as much as possible, the pencil of light rays 8 emitted from the infrared light emitting region 4 is desirably projected to the eye 6 of the viewer via the eyepiece optical system. With such a configuration, the probability that the pencil of light rays 8 is eclipsed by an eyelid of the viewer can be reduced, so it is possible to improve the accuracy and robustness of line-of-sight sensing and detection. Furthermore, the size of the light emitting apparatus 1 can also be reduced.

### Eyepiece Optical System

The one that forms the exit pupil 18 such that the display surface of the display region 3 is expanded, that is, the one that at least guides the light 7 emitted from the display surface of the display region 3 to the exit pupil 18, can be selected as the eyepiece optical system. At this time, the light emitting elements (display light emitting elements) may be disposed on an optical axis (on-axis) or may be disposed outside the optical axis (off-axis). Examples in which the light emitting elements are disposed on the optical axis include a Fresnel lens and a pancake lens. Examples in which the light emitting elements are disposed outside the optical axis include a free-form surface lens and a bird bath type optical system.

In FIG. 5, the eyepiece optical system 19 is made up of a pancake lens including two lenses (optical members), that is, a first lens 19a and a second lens 19b. The pancake lens may be configured to include at least a polarizer, a phase plate, a translucent reflective surface, a lens, and a polarizing beam splitter (PBS) arranged to switch between transmission and reflection according to a polarization state.

When the eyepiece optical system, such as a pancake lens and a bird bath type optical system, is used, most of the infrared light emitting elements get losses due to poor lens transmittance. For this reason, it is desirable to increase the reflectance of the second upper electrodes 113 in the infrared light emitting elements 101.

### Deflector

Depending on the arrangement of the infrared light emitting region 4, a deflector having a function to change the direction (traveling direction) of the light 8 emitted from the infrared light emitting elements 101 may be disposed between the infrared light emitting region 4 and the eyepiece optical system 19. In FIG. 5, the deflector 20 is disposed between the display surface of the display region 3 and the eyepiece optical system 19 so as to overlap the infrared light emitting region 4. A condensing function and a diffusion function may be imparted to the deflector 20. The one that has a function to bend the light 8 emitted from the infrared light emitting region 4 toward the eye 6 of the viewer may be selected as the deflector disposed between the infrared light emitting region 4 and the eyepiece optical system 19. The deflector may be a meta surface, a liquid crystal diffraction grating, or the like, or may be any one of them imparted with a lens function.

Light (infrared light) emitted from the infrared light emitting region is emitted most intensively in the normal direction of the light emitting apparatus. Therefore, the deflector is desirably disposed so as to overlap the infrared light emitting region in a plan view of the light emitting apparatus. From the viewpoint of size reduction, the deflector can be disposed between the display surface of the display region of the light emitting apparatus and the eyepiece optical system to project light emitted from the infrared light emitting elements through the eyepiece optical system onto the eye of the viewer.

### [Uses of Light Emitting Apparatuses According to Embodiments of Present Disclosure]

The light emitting apparatuses according to the embodiments of the present disclosure each may be used as a component member of a display apparatus or a component member of an illumination apparatus. Other than those, there are uses, such as an exposure light source of an electrophotographic image forming apparatus and a light emitting apparatus including a color filter for a backlight or white light source of a liquid crystal display apparatus.

A display apparatus may be an image information processing apparatus. The image information processing apparatus includes an image input unit that enters image information from an area CCD, a linear CCD, a memory card, or the like, and an information processing unit that processes input information. The image information processing apparatus displays the input image on a display unit.

A display unit of an image capturing apparatus or ink-jet printer may have a touch panel function. A drive system of the touch panel function may be an infrared radiation method, a capacitance method, a resistive film method, or an electromagnetic induction method and is not limited. A display apparatus may be used as a display unit of a multifunction printer.

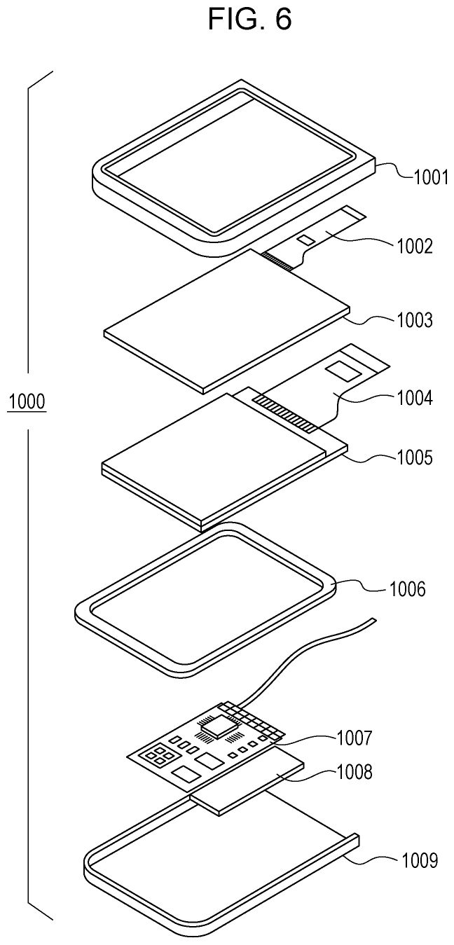

Hereinafter, application examples of the light emitting apparatus will be described with reference to FIGS. 6 to 9B.

The light emitting apparatus according to the embodiment of the present disclosure can make up a display apparatus in combination with active elements, such as transistors, connected to the light emitting apparatus.

FIG. 6 is a schematic view that shows an example of a display apparatus using the light emitting apparatus according to the present embodiment. The display apparatus 1000 may include a touch panel 1003, a display panel 1005, a frame 1006, a circuit board 1007, and a battery 1008 between a top cover 1001 and a bottom cover 1009. A flexible printed circuit (FPC) 1002 is connected to the touch panel 1003. A flexible printed circuit (FPC) 1004 is connected to the display panel 1005. Active elements, such as transistors, can be disposed on the circuit board 1007. In FIG. 6, transistors are printed on the circuit board 1007. The battery 1008 does not need to be provided when the display apparatus is not a mobile device, or may be provided at another position even when the display apparatus is a mobile device. The light emitting apparatus according to the present embodiment may be used as the display panel 1005. The display region (light emitting region) of the light emitting apparatus that functions as the display panel 1005 is connected to active elements, such as transistors, disposed on the circuit board 1007 and operates.

The display apparatus may include red, green, and blue color filters. The red, green, and blue color filters may be arranged in a delta array.

The display apparatus may be used in a display unit of a mobile terminal. In this case, the light emitting apparatus may have a display function and an operating function. The mobile terminal may be a cellular phone, such as a smartphone, a tablet, a head mounted display, or the like.

The light emitting apparatus according to the embodiment of the present disclosure may be applied to an image capturing apparatus including at least an optical unit having a plurality of lenses, an image pickup element arranged to receive light passing through the optical unit, and a display unit arranged to display an image captured by the image pickup element. The display apparatus using the light emitting apparatus according to the present embodiment may be used in a display unit of an image capturing apparatus including an optical unit having a plurality of lenses and image pickup elements that receive light passing through the optical unit. The image capturing apparatus may include a display unit that displays information acquired by the image pickup elements. The display unit may be a display unit exposed to the outside of the image capturing apparatus or may be a display unit disposed in a viewfinder. The image capturing apparatus may be a digital camera or a digital camcorder.

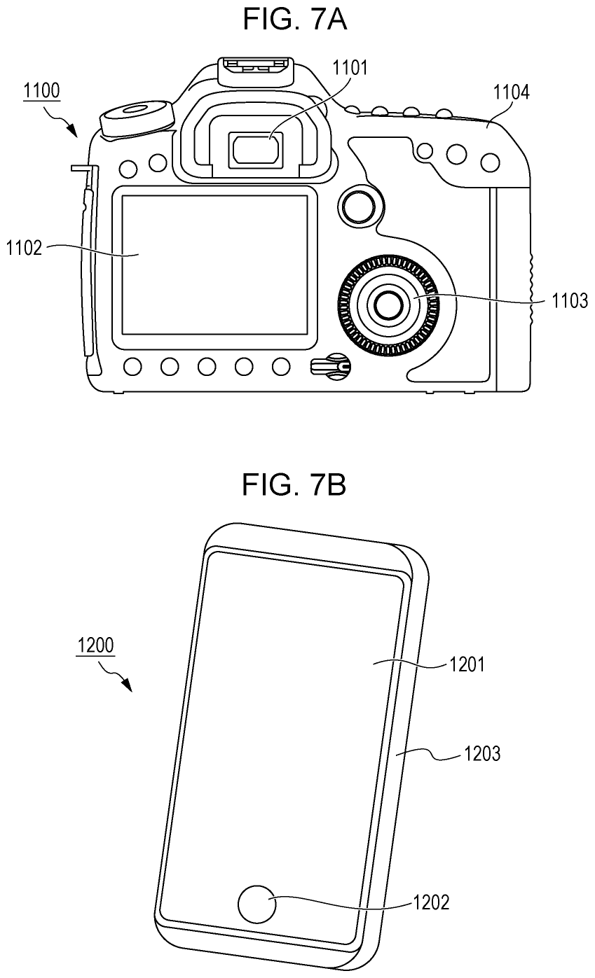

FIG. 7A is a schematic view that shows an example of an image capturing apparatus using the display apparatus according to the embodiment of the present disclosure. An image capturing apparatus 1100 may include a viewfinder 1101, a back display 1102, an operating portion 1103, and a housing 1104. The light emitting apparatus according to the present embodiment is applicable to the viewfinder 1101 or the back display 1102, which is the display unit. In this case, the display region (light emitting region) of the light emitting apparatus may display not only an image to be captured but also environmental information, an image capturing instruction, and the like. The environmental information may include the intensity of external light, the direction of external light, the moving speed of a subject, a possibility that a subject is shielded by a shielding material, or the like.

Since suitable timing for imaging is mostly a slight amount of time, information is desirably displayed as early as possible. Therefore, the light emitting apparatus in which the light emitting elements using organic luminescent material, such as organic EL elements, that is, the organic light emitting elements are disposed in the display region (light emitting region) can be used for the viewfinder 1101 or the back display 1102. This is because an organic light emitting element has a higher response speed. The light emitting apparatus using organic light emitting elements is more suitably used than a liquid crystal display apparatus for these apparatuses of which a higher display speed is desired.

The image capturing apparatus 1100 includes an optical unit (not shown). The optical unit has a plurality of lenses and forms an image on the image pickup elements accommodated in the housing 1104. The plurality of lenses is capable of adjusting a focal point by adjusting the relative positions of the lenses. This operation can be automatically performed. The image capturing apparatus may be called a photoelectric conversion apparatus. The photoelectric conversion apparatus can include not sequentially capturing an image but a method of detecting a difference from a previous image, a method of extracting an image from an image being constantly recorded, or the like, as a method of capturing an image.

The light emitting apparatus according to the embodiment of the present disclosure may be applied to a display unit of an electronic device. In this case, the light emitting apparatus may have a display function and an operating function. The electronic device may include a display unit including the light emitting apparatus according to the embodiment of the present disclosure, a housing on which the display unit is provided, and a communication unit provided in the housing and arranged to communicate with an external source. The electronic device may be a mobile terminal or the like. The mobile terminal may be a cellular phone, such as a smartphone, a tablet, a head mounted display, or the like.

FIG. 7B is a schematic view that shows an example of an electronic device using the light emitting apparatus according to the embodiment of the present disclosure. An electronic device 1200 includes a display unit 1201, an operating portion 1202, and a housing 1203. The housing 1203 may contain a circuit, a printed circuit board having the circuit, a battery, and a communication unit. The operating portion 1202 may be a button or may be a touch panel-type response unit. The operating portion may be a biometric authentication unit that identifies a fingerprint to, for example, release a lock. The electronic device including a communication unit may be regarded as a communication device. The electronic device may further have a camera function by including a lens and image pickup elements. An image captured by the camera function is shown on the display unit. The electronic device may be a smartphone, a notebook computer, or the like. The light emitting apparatus according to the present embodiment may be used as the display unit 1201.

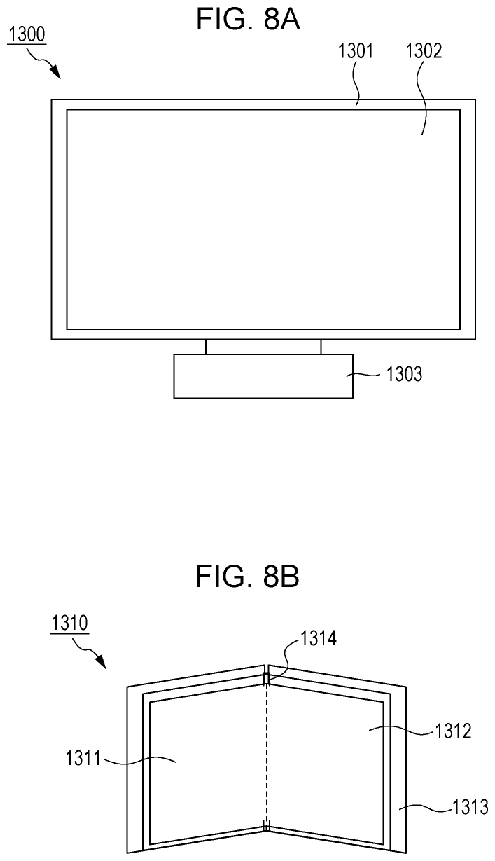

FIG. 8A is a schematic view that shows an example of a display apparatus using the light emitting apparatus according to the embodiment of the present disclosure. FIG. 8A is a display apparatus, such as a television monitor and a PC monitor. The display apparatus 1300 includes a frame 1301 and a display unit 1302. The light emitting apparatus according to the present embodiment may be used as the display unit 1302.

The display apparatus 1300 may include the frame 1301 and a base 1303 that supports the display unit 1302. The base 1303 is not limited to the mode of FIG. 8A. The bottom side of the frame 1301 may serve as a base. The frame 1301 and the display unit 1302 may be curved.

The radius of curvature may be greater than or equal to 5000 mm and less than or equal to 6000 mm.

FIG. 8B is a schematic view that shows another example of a display apparatus using the light emitting apparatus according to the embodiment of the present disclosure. A display apparatus 1310 of FIG. 8B is configured to be foldable, and is a so-called foldable display apparatus. The display apparatus 1310 includes a first display unit 1311, a second display unit 1312, a housing 1313, and a folding point 1314. The light emitting apparatus according to the present embodiment may be used as the first display unit 1311 and the second display unit 1312. The first display unit 1311 and the second display unit 1312 may make up a seamless one-sheet display apparatus. The first display unit 1311 and the second display unit 1312 may be separated at the folding point 1314. The first display unit 1311 and the second display unit 1312 may respectively display different images or the first and second display units 1311, 1312 may display one image.

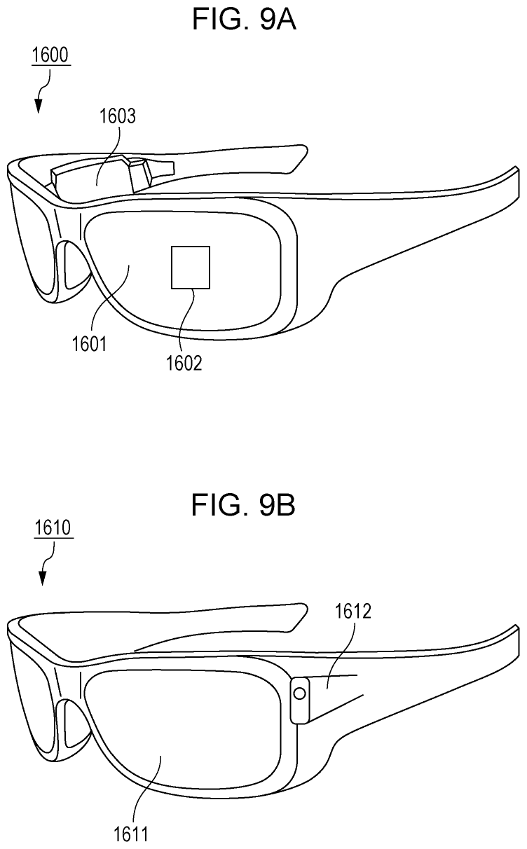

Further application examples of the light emitting apparatus according to the embodiment of the present disclosure will be described with reference to FIGS. 9A and 9B.

The light emitting apparatus is applicable to a wearable system as a wearable device, such as smartglasses, a head mounted display (HMD), and a smart contact lens. An image capturing and display apparatus used in such application examples includes an image capturing apparatus capable of performing photoelectric conversion of visible light and a display apparatus capable of emitting visible light.

FIG. 9A illustrates glasses 1600 (smartglasses) according to one application example. An image capturing apparatus 1602, such as a CMOS sensor and an SPAD, is provided on the surface side of a lens 1601 of the glasses 1600. In addition, the light emitting apparatus according to the present embodiment is provided on the back surface side of the lens 1601.

The glasses 1600 further include a controller 1603. The controller 1603 functions as a power supply to supply electric power to the image capturing apparatus 1602 and the light emitting apparatus according to any one of the embodiments. The controller 1603 controls the operations of the image capturing apparatus 1602 and the light emitting apparatus. An optical system for condensing light to the image capturing apparatus 1602 is formed in the lens 1601.

FIG. 9B illustrates glasses 1610 (smartglasses) according to one application example. The glasses 1610 include a controller 1612. An image capturing apparatus corresponding to the image capturing apparatus 1602 and a light emitting apparatus (or a display apparatus including the light emitting apparatus) are mounted on the controller 1612. An optical system for projecting light emitted from the light emitting apparatus in the controller 1612 is formed in a lens 1611, and an image is projected onto the lens 1611. The controller 1612 functions as a power supply to supply electric power to the image capturing apparatus and the light emitting apparatus and also controls the operations of the image capturing apparatus and the light emitting apparatus. The controller 1612 may include a line-of-sight detection unit that detects the line of sight of a wearer. Infrared light may be used to detect the line of sight. An infrared emitting unit emits infrared light to the eye of a user gazing at a display image. Infrared light emitted and reflected from the eye is detected by an image capturing unit including light receiving elements. Thus, a captured image of the eye is obtained. A reducer that reduces light from the infrared emitting unit to the display unit in a plan view is provided, so a decrease in image quality is reduced.

The line-of-sight of the user toward the display image is detected from the captured image of the eye, obtained through imaging with infrared light. A selected known technique may be applied to line-of-sight detection using a captured image of an eye. In an example, a line-of-sight detection method based on a Purkinje image caused by reflection of irradiation light on a cornea may be used.

More specifically, a line-of-sight detection process based on a pupil-cornea reflection method is performed. A line-of-sight vector indicating the orientation (rotational angle) of the eye is calculated in accordance with the pupil image contained in a captured image of the eye and a Purkinje image by using the pupil-cornea reflection method. Thus, the line of sight of a user is detected.

The light emitting apparatus according to the embodiment of the present disclosure may include an image capturing apparatus having light receiving elements and may control a display image in accordance with information about the line of sight of a user from the image capturing apparatus.

Specifically, the display apparatus including the light emitting apparatus determines a first display region at which the user gazes and a second display region other than the first display region in accordance with the line-of-sight information. A first display region and a second display region may be determined by the controller of the display apparatus or a first display region and a second display region determined by an external controller may be received. In a display region of the display apparatus, a display resolution of the first display region may be controlled so as to be higher than a display resolution of the second display region. In other words, the resolution of the second display region may be made lower than the resolution of the first display region.

A display region includes a first display region and a second display region different from the first display region, and a region having a higher priority is determined in accordance with line-of-sight information from among the first display region and the second display region. A first field of view region and a second field of view region may be determined by the controller of the display apparatus or a first field of view region and a second field of view region determined by an external controller may be received. The resolution of a region having a higher priority may be controlled so as to be higher than the resolution of a region other than the region having a higher priority. In other words, the resolution of a region having a relatively lower priority may be decreased.

AI may be used to determine a first field of view region or a region having a higher priority. AI may be a model configured to estimate an angle of a line of sight and a distance to an object ahead of the line of sight from an image of an eye by using the images of the eye and corresponding directions in which the eye of the image is actually viewing as training data. The light emitting apparatus, the display apparatus, the image capturing apparatus, or an external apparatus may include an AI program. When the external apparatus includes an AI program, estimated results are transmitted to the light emitting apparatus via communication.

When display control is performed in accordance with line-of-sight detection, the display apparatus is suitably applicable to smartglasses further including an image capturing apparatus that captures an outside image. The smartglasses are capable of displaying captured outside information in real time.

According to the embodiment of the present disclosure, it is possible to improve the light extraction efficiency of visible light emitted from a display light emitting element and infrared light emitted from an infrared light emitting element in a light emitting apparatus.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-049554 filed Mar. 26, 2024, which is hereby incorporated by reference herein in its entirety.

What is claimed is:

1. A light emitting apparatus comprising:
a display region and an infrared light emitting region on a substrate;
a plurality of display light emitting elements disposed in the display region; and
a plurality of infrared light emitting elements disposed in the infrared light emitting region, wherein
in a plan view of the substrate, the display region and the infrared light emitting region are in a positional relationship not overlapping each other,
each of the display light emitting element and the infrared light emitting element is made by laminating a lower electrode, a functional layer including a light emitting layer, and an upper electrode in this order from the substrate side, and
a reflectance of the upper electrode of the infrared light emitting element at an infrared wavelength is higher than a reflectance of the upper electrode of the display light emitting element at the infrared wavelength.

2. The light emitting apparatus according to claim 1, wherein the upper electrode of the display light emitting element and/or the upper electrode of the infrared light emitting element is a semi-transparent electrode.

3. The light emitting apparatus according to claim 1, wherein a thickness of the upper electrode of the infrared light emitting element is greater than a thickness of the upper electrode of the display light emitting element.

4. The light emitting apparatus according to claim 1, wherein a reflectance of the upper electrode of the infrared light emitting element at the infrared wavelength is higher than or equal to 15%.

5. The light emitting apparatus according to claim 1, wherein the infrared light emitting region is disposed outside the display region.

6. The light emitting apparatus according to claim 1, wherein the display region and the infrared light emitting region are provided on the same substrate.

7. The light emitting apparatus according to claim 1, wherein the functional layer is an organic compound layer made of an organic compound.

8. The light emitting apparatus according to claim 1, further comprising an eyepiece optical system arranged to guide light from a display surface of the display region to an exit pupil, wherein
the light from the infrared light emitting element is configured to be projected to an eye of a viewer through the eyepiece optical system.

9. The light emitting apparatus according to claim 8, wherein the eyepiece optical system includes a polarizer, a phase plate, a translucent reflective surface, a lens, and a polarizing beam splitter arranged to switch between transmission and reflection according to a polarization state.

10. The light emitting apparatus according to claim 9, further comprising a deflector having a function to change a traveling direction of light emitted from the infrared light emitting element, wherein
the deflector is disposed between the display surface of the display region and the eyepiece optical system so as to overlap the infrared light emitting region in a plan view of the light emitting apparatus.

11. A light emitting apparatus comprising:
a display region and an infrared light emitting region on a substrate;
a plurality of display light emitting elements disposed in the display region; and
a plurality of infrared light emitting elements disposed in the infrared light emitting region, wherein
in a plan view of the substrate, the display region and the infrared light emitting region are in a positional relationship not overlapping each other,
each of the display light emitting element and the infrared light emitting element is made by laminating a lower electrode, a functional layer including a light emitting layer, and an upper electrode in this order from the substrate side,
a reflectance of the upper electrode of the infrared light emitting element at an infrared wavelength is higher than a reflectance of the upper electrode of the display light emitting element at the infrared wavelength, and
the upper electrode that is a component of the infrared light emitting element and the upper electrode that is a component of the display light emitting element differ from each other in composition.

12. The light emitting apparatus according to claim 11, wherein the upper electrode of the display light emitting element and/or the upper electrode of the infrared light emitting element is a semi-transparent electrode.

13. The light emitting apparatus according to claim 11, wherein a reflectance of the upper electrode of the infrared light emitting element at the infrared wavelength is higher than or equal to 15%.

14. The light emitting apparatus according to claim 11, wherein the infrared light emitting region is disposed outside the display region.

15. The light emitting apparatus according to claim 11, wherein the display region and the infrared light emitting region are provided on the same substrate.

16. The light emitting apparatus according to claim 11, wherein the functional layer is an organic compound layer made of an organic compound.

17. The light emitting apparatus according to claim 11, further comprising an eyepiece optical system arranged to guide light from a display surface of the display region to an exit pupil, wherein
the light from the infrared light emitting element is configured to be projected to an eye of a viewer through the eyepiece optical system.

18. The light emitting apparatus according to claim 17, wherein the eyepiece optical system includes a polarizer, a phase plate, a translucent reflective surface, a lens, and a polarizing beam splitter arranged to switch between transmission and reflection according to a polarization state.

19. The light emitting apparatus according to claim 18, further comprising a deflector having a function to change a traveling direction of light emitted from the infrared light emitting element, wherein
the deflector is disposed between the display surface of the display region and the eyepiece optical system so as to overlap the infrared light emitting region in a plan view of the light emitting apparatus.

20. A display apparatus comprising:
the light emitting apparatus according to claim 1; and
a transistor connected to the light emitting apparatus.

21. An image capturing apparatus comprising:
an optical unit having a plurality of lenses;
an image pickup element arranged to receive light having passed through the optical unit; and
a display unit arranged to display an image captured by the image pickup element, wherein
the display unit includes the light emitting apparatus according to claim 1.

22. An electronic device comprising:
a display unit including the light emitting apparatus according to claim 1;
a housing on which the display unit is provided; and
a communication unit provided in the housing.
